(19) United States
(12) Patent Application Publication
(10) Pub. No.: US 2005/0133921 A1
(43) Pub. Date: Jun. 23, 2005

(54) Semiconductor device

(76) Inventors: Tomohiro Oki, Yokohama-shi (JP); Hiroyuki Kamijo, Sagamihara-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 10/975,081

(22) Filed: Oct. 28, 2004

(30) Foreign Application Priority Data
Oct. 30, 2003 (JP) 2003-370986

(51) Int. Cl. H01L 29/40

(52) U.S. Cl. 257/758

(57) ABSTRACT

A semiconductor device comprises a semiconductor substrate, a multilayer interconnect provided on the semiconductor substrate, the multilayer interconnect comprising a plurality of layers of insulating films and interconnects, at least one fuse interconnect provided in a layer higher than the multilayer interconnect, and a moisture absorption preventing hollow member including a hollow structure, the moisture absorption preventing hollow member selectively surrounding the at least one fuse interconnect and reaching a surface of the semiconductor substrate through the multilayer interconnect, the moisture absorption preventing hollow member comprising a material having a lower hygroscopicity than the plurality of layers of insulating films.

### CROSS-REFERENCE TO RELATED APPLICATIONS

This application is based upon and claims the benefit of priority from prior Japanese Patent Application No. 2003-370986, filed Oct. 30, 2003, the entire contents of which are incorporated herein by reference.

### BACKGROUND OF THE INVENTION

1. Field of the Invention

The present invention relates to a semiconductor device including a fuse interconnect.

2. Description of the Related Art

A redundancy technique has been known as one of the important technique for avoiding the difficulty of obtaining good products resulting from an increase of the integration level of semiconductor devices and improving the yield thereof (JPN. PAT. APPLN. KOKAI Publication No. 2000-299381).

According to the redundancy technique, for instance, the semiconductor device is provided with a redundancy circuit in order to save a circuit which becomes failure in the manufacture process of the semiconductor device. The redundancy circuit includes an interconnect (wiring) calling a fuse interconnect. The fuse interconnect is cut to make a changeover to a preliminary circuit, and thereby, the circuit is saved.

FIG. 11 is a top plan view showing a semiconductor device including a conventional fuse interconnect. FIG. 12 is a cross-section view taken along the line 12A-12A′ of FIG. 11. FIG. 11 and FIG. 12 show a state that the fuse interconnect is cut.

In FIG. 11 and FIG. 12, 71 shows a semiconductor substrate, 72, shows an interlayer insulating film, 73 shows a contact plug, 74 shows an interlayer insulating film, 75 shows an interconnect, 76 shows an interlayer insulating film, 77 shows a damascene interconnect (interconnect and plug), 78 shows an moisture absorption preventing film, 79 shows a an interlayer insulating film, 80 shows damascene interconnect (interconnect and plug), 81 shows a fuse interconnect (wiring), 82 shows a passivation film, and 83 shows a fuse window. Laser beam (not shown) is irradiated in the fuse window 83 to cut (blowout) the fuse interconnect 81.

A low dielectric constant insulating film called low-k film is used for each of the interlayer insulating films 72, 74 and 76. This kind of low dielectric constant insulating film has a hygroscopicity higher than SiO₂ film. In order to prevent moisture from being absorbed into the interlayer insulating films 72, 74 and 76, the moisture absorption preventing film 78 is formed on the interlayer insulating film 76.

However, the surface of the interlayer insulating film 76 under the fuse window 83 is exposed after the fuse interconnect 81 is cut. The moisture intrudes into the exposed surface, and moisture 84 diffuses in the interlayer insulating film 76. If the moisture 84 intrudes into the circuit of the semiconductor device, a leakage current is increased between interconnects or the operation failure of the circuit occurs due to the corrosion of the contact plug 73 or damascene interconnect 77.

### BRIEF SUMMARY OF THE INVENTION

A semiconductor device according to an aspect of the present invention comprises a semiconductor substrate; a multilayer interconnect provided on the semiconductor substrate, the multilayer interconnect comprising a plurality of layers of insulating films and interconnects; at least one fuse interconnect provided in a layer higher than the multilayer interconnect; and a moisture absorption preventing hollow member including a hollow structure, the moisture absorption preventing hollow member selectively surrounding the at least one fuse interconnect and reaching a surface of the semiconductor substrate through the multilayer interconnect, the moisture absorption preventing hollow member comprising a material having a lower hygroscopicity than the plurality of layers of insulating films.

A semiconductor device according to another aspect of the present invention comprises a semiconductor substrate; a multilayer interconnect provided on the semiconductor substrate, the multilayer interconnect comprising a plurality of layers of insulating films and interconnects; at least one fuse interconnect provided in the multilayer interconnect; and an moisture absorption preventing hollow member including a hollow structure, the moisture absorption preventing hollow member selectively surrounding the at least one fuse interconnect and reaching the surface of the semiconductor substrate through the multilayer interconnect, moisture absorption preventing hollow member comprising a material having a lower hygroscopicity than the plurality of layers of insulating films.

### BRIEF DESCRIPTION OF THE SEVERAL VIEWS OF THE DRAWING

FIG. 1 is a top plan view showing a semiconductor device including a fuse interconnect according to the first embodiment of the present invention;

FIG. 2 is a cross-sectional view taken along the line 2A-2A′ of FIG. 1;

FIG. 3 is a top plan view showing a semiconductor device including a fuse interconnect according to the second embodiment of the present invention;

FIG. 4 is a cross-sectional view taken along the line 4A-4A′ of FIG. 3;

FIG. 5 is a top plan view showing a semiconductor device including a fuse interconnect according to the third embodiment of the present invention;

FIG. 6 is a cross-sectional view taken along the line 6A-6A′ of FIG. 5;

FIG. 7 is a top plan view showing a semiconductor device including a fuse interconnect according to the fourth embodiment of the present invention;

FIG. 8 is a cross-sectional view taken along the line 8A-8A′ of FIG. 7;

FIG. 9 is a top plan view showing a semiconductor device including a fuse interconnect according to the fifth embodiment of the present invention;

FIG. 10 is a cross-sectional view taken along the line 10A-10A′ of FIG. 9;

FIG. 11 is a top plan view showing a semiconductor device including a conventional fuse interconnect; and

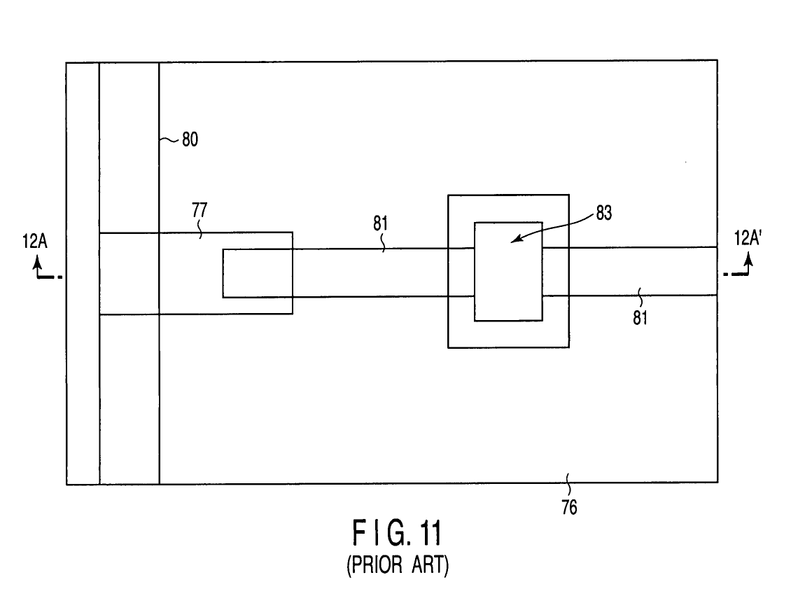

FIG. 12 is a cross-section view taken along the line 12A-12A′ of FIG. 11.

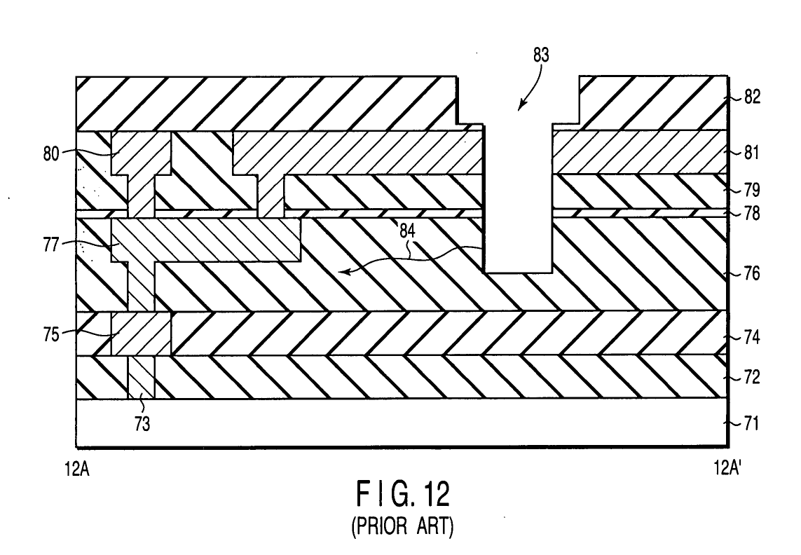

### DETAILED DESCRIPTION OF THE INVENTION

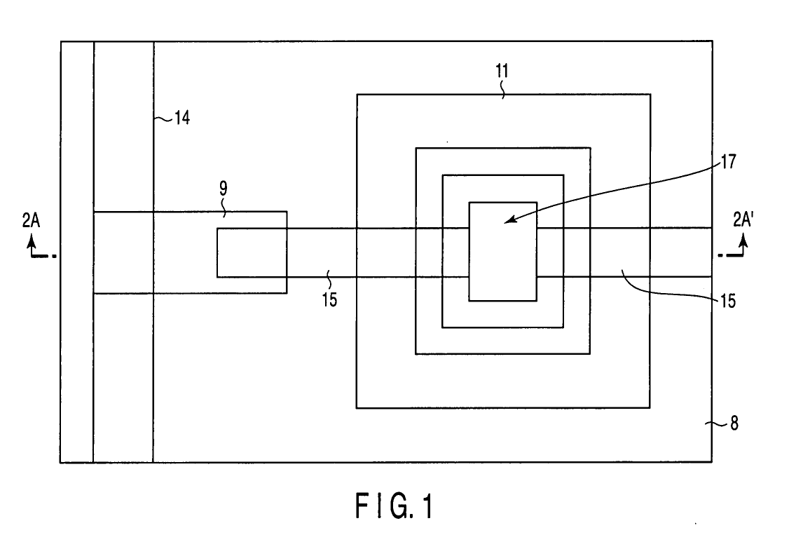

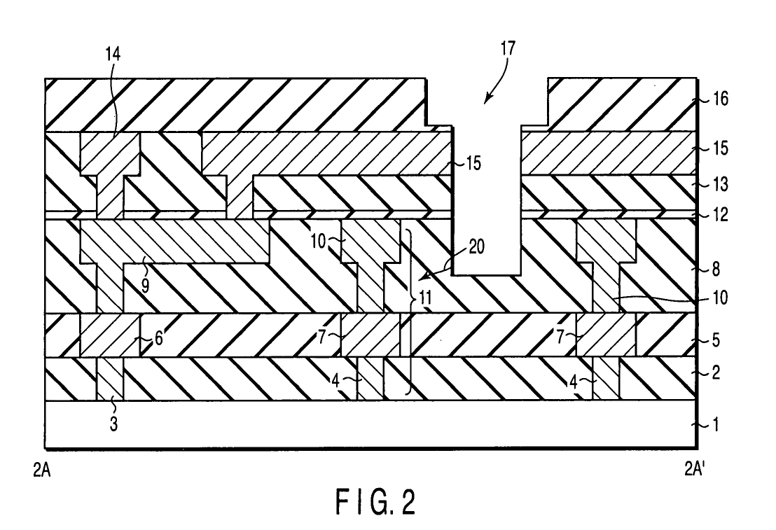

FIG. 1 is a top plan view showing a semiconductor device including a fuse interconnect according to the first embodiment of the present invention. FIG. 2 is a cross-sectional view taken along the line 2A-2A′ of FIG. 1. FIG. 1 and FIG. 2 show a state that the fuse interconnect is cut.

The semiconductor device according to the first embodiment is broadly comprises silicon substrate 1, a multilayer interconnect provided on the silicon substrate 1 and including a plurality of interlayer insulating films 2, 5, 8, and a plurality of interlayer interconnects 7, 10, a fuse interconnect 15 provided in a higher layer than the multilayer interconnect, and a moisture absorption preventing hollow member including a hollow structure, which reaches the silicon substrate 1 through the surface of the multilayer interconnect and comprises a material having a lower hygroscopicity than the interlayer insulating films 2, 5 and 8.

Incidentally, an moisture permeability preventing hollow member including a hollow structure, which comprises a material having moisture permeability lower than interlayer insulating films 2, 5 and 8 can be used. Whether or not the member is depends on the degree of the permeability. That is, even the surfaces of interlayer insulating films 2, 5 and 8 are exposed, moisture permeability preventing hollow member can be used so long it blocks the diffusion of moisture intruded from the exposed surface into the interconnects 7 and 10.

The semiconductor device according to the first embodiment will be detailedly described below.

The first interlayer insulating film 2 is provided on the silicon substrate 1. A diffusion layer (not shown) is provided on the surface of the silicon substrate 1 The diffusion layer is a source/drain diffusion layer of a MOS transistor, for example. The low-k film is used as the first interlayer insulating film 2. The following insulating film is given as the low-k film. The insulating film comprises at least one of fluorine doped silicon oxide-film (SiOF), carbon doped silicon oxide film (SiOC), organic coating insulating film formed from resin having siloxane bond as a main structure, organic coating insulating film formed from resin having C—C bond as a main structure or organic coating insulating film formed from resin having C═C bond as a main structure. These low-k film have high hygroscopicity (moisture permeability), in general.

The contact plug 3 and plug 4 are provided in the first interlayer insulating film 2. The contact plug 3 contacts with the diffusion layer (not shown), and forms a part of a circuit of the device. The circuit is a circuit included in a system LSI, for example. The plug 4 has a closed ring shape (rectangular shape in FIG. 2). The plug 4 forms a part of the moisture absorption preventing hollow member.

The contact plug 3 and plug 4 are formed of the same material (plug material), for example, W (tungsten). Thereby, the contact plug 3 and the plug 4 can be formed in the same process. Therefore, even if the plug 4 is introduced, an increase of the process or complication of process does not occur.

The second interlayer insulating film 5 is provided on the first interlayer insulating film 2. The same low-k film as the first interlayer insulating film 2 is used as the second interlayer insulating film 5. The interconnects 6 and 7 are provided in the second interlayer insulating film 5. The interconnect 6 contacts with the contact plug 3, and forms a part of the circuit of the device. The interconnect 7 has a closed ring shape (rectangular shape in FIG. 2). The interconnect 7 contacts with the plug 4, and forms a part of the moisture absorption preventing hollow member.

The interconnects 6 and 7 are formed of the same material (interconnect material), for example, Cu (copper). Thereby, the interconnects 6 and 7 are formed in the same process. Therefore, even if the interconnect 7 is introduced, an increase of process or complication of the process does not occur. In a case that the material of the interconnects 6 and 7 is Cu, a barrier metal film is provided around the interconnects 6 and 7. For example, a monolayer film selected from a group consisting of Ta film, TaN film, Ti film, TiN film, TiSiN film and WN film, or a stacked film comprising at least two films selected from the group is given as the barrier metal film.

Here, the contact plug 3 and the interconnect 6 are formed in the process independent from each other, the contact plug 3 and the interconnect 6 may be formed in the same process such as dual damascene process.

The third interlayer insulating film 8 is provided on the second interlayer insulating film 5. In a case that the material of the interconnects 6 and 7 is Cu, a Cu anti-diffusion film (not shown) is provided on the insulating film 5, interconnects 6 and 7. For example, a film (single or multiple layer) including at least one of silicon nitride film, carbon doped silicon nitride film and silicon carbide film is given as the Cu anti-diffusion film. The same low-k film as the first interlayer insulating film 2 is used as the third interlayer insulating film 8. The damascene interconnects (interconnect and plug) 9 and 10 are provided in the third interlayer insulating film 8. The damascene interconnects 9 and 10 are formed by a known dual damascene process.

The damascene interconnect 9 contacts with the interconnect 6, and forms a part of the circuit of the device. The damascene interconnect 10 has a closed ring shape (rectangular shape in FIG. 2). The damascene interconnect 10 contacts with the interconnect 7, and forms a part of the moisture absorption preventing hollow member.

The damascene interconnects 9 and 10 are formed of the same material, for example, Cu (copper). Thereby, the damascene interconnects 9 and 10 are formed in the same dual damascene process. Therefore, even if the damascene interconnect 10 is introduced, an increase of process or complication of the process does not occur. In a case that the material of the damascene interconnects 9 and 10 is Cu, a barrier metal film is provided around the damascene interconnects 9 and 10.

The moisture absorption preventing hollow member 11 comprises the damascene interconnect 10, the interconnect 7 and th plug 4. Even if these damascene interconnect 10, interconnect 7 and plug 4 are introduced, an increase of process or complication of the process does not occur, then, even if the moisture absorption preventing hollow member 11 is introduced, the increase of process or complication of the process does not occur.

An moisture absorption preventing film 12 is provided on the third interlayer insulating film 8. In a case that the interconnect material is Cu, a film having a Cu anti-diffusion function in addition to the moisture absorption preventing function is used as the moisture absorption preventing film 12. The upper surfaces of the damascene interconnects 9 and 10 are covered with the moisture absorption preventing film 12. For example, a film (single or multiple layer) including at least one of silicon oxide film, silicon nitride film, carbon doped silicon nitride film and silicon carbide film is given as the moisture absorption preventing film 12.

A fourth interlayer insulating film 13 is provided on the moisture absorption preventing film 12. The fourth interlayer insulating film 13 is a silicon oxide film formed by plasma CVD process, for example. The damascene interconnect 14 and fuse interconnect 15 are provided in the fourth interlayer insulating film 13. The damascene interconnect 14 and the fuse interconnect 15 contact with the lower-layer damascene interconnect 9. A passivation film 16 is provided on the fourth interlayer insulating film 13. The passivation film 16 is formed with a fuse window 17.

In a case that the fuse interconnect 15 is cut, laser beam is irradiated in-the fuse window 17. The fuse interconnect 15 is cut by the irradiation of the laser. In addition, a through hole is formed in the fourth interlayer insulating film 13 and the moisture absorption preventing film 12 which lie beneath the cut portion (blowout portion) of the fuse interconnect 15, further an opening is formed on a surface of the third interlayer insulating film 8 under the through hole by the irradiation of the laser. The opening may reach the surface of the second interlayer insulating film 5.

Further, the surface of the third interlayer insulating film 5 which lie beneath the cut portion of the fuse interconnect 15 is removed. Therefore, there is a possibility that moisture 20 intrudes into the first to third interlayer insulating films 2, 5 and 8 from the exposed surface of the third interlayer insulating film 8.

However, according to the present embodiment, even if the moisture 20 intrudes into the first to third interlayer insulating films 2, 5 and 8, the diffusion of the moisture 20 to the circuit of the device is blocked. Therefore, the increase of leakage current between interconnects, or the operation failure of the circuit resulting from the corrosion of the contact plug 3, interconnect 7 or damascene interconnect 9 is prevented.

The method of manufacturing the semiconductor device of the present embodiment is same as conventional method except including the step of manufacturing the moisture absorption preventing hollow member 11 (damascene interconnects 10, plug 4). That is, the method of present embodiment is same as conventional method except forming the plug 4 in the step of forming the contact plug 3 at the same time, and forming damascene interconnects 10 in the step of forming the damascene interconnects 9 at the same time.

In the present embodiment, the multilayer interconnect of two layers case is explained, the similar effect can be obtained even in a multilayer interconnect of three or more layers case by providing the moisture absorption preventing hollow member 11 same as the present embodiment.

Moreover in the present embodiment, the silicon substrate 1 is use as the semiconductor substrate, SOI substrate, substrate including a strained silicon region and substrate including a SiGe region can be used.

In the present embodiment, the conductive material is used as the material of the moisture absorption preventing hollow member 11, an insulating material can be used.

The moisture absorption preventing hollow member 11 can be formed of interconnect or plug only.

### SECOND EMBODIMENT

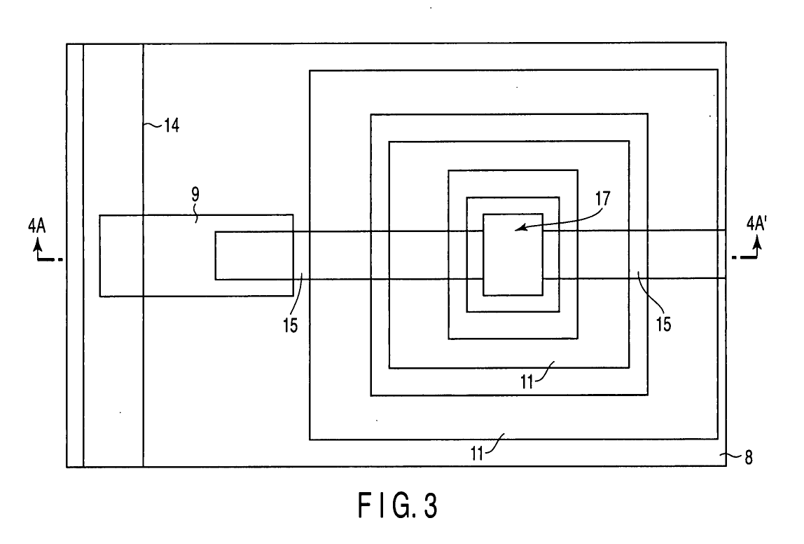

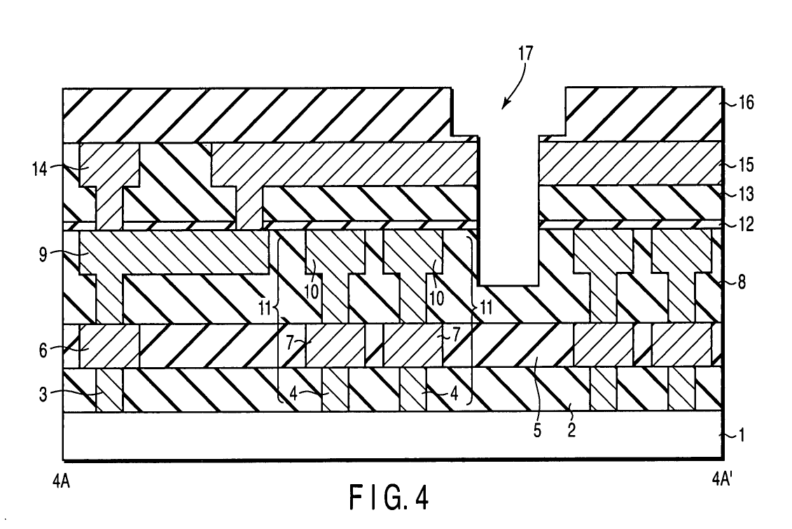

FIG. 3 is a top plan view showing a semiconductor device including a fuse interconnect according to the second embodiment of the present invention. FIG. 4 is a cross-sectional view taken along the line 4A-4A′ of FIG. 3. FIG. 3 and FIG. 4 show a state that the fuse interconnect is cut. In the following drawings, the same reference numerals are used to designate portions corresponding to the preceding drawings, and the details are omitted.

The present embodiment differs from the first embodiment in that the moisture absorption preventing hollow member 11 is arranged double. Thereby, it is possible to more effectively prevent moisture from intruding into the circuit of the device. Besides, the same effect as the first embodiment is obtained, and modifications are possible like the first embodiment.

In FIG. 3 and FIG. 4, for simplification, there is shown a double-structural moisture absorption preventing hollow member 11, however, a three-layer moisture absorption preventing hollow member 11 or more can be used. Realistically, a triple-structural or quintuple-structural moisture absorption preventing hollow member 11 is used.

### THIRD EMBODIMENT

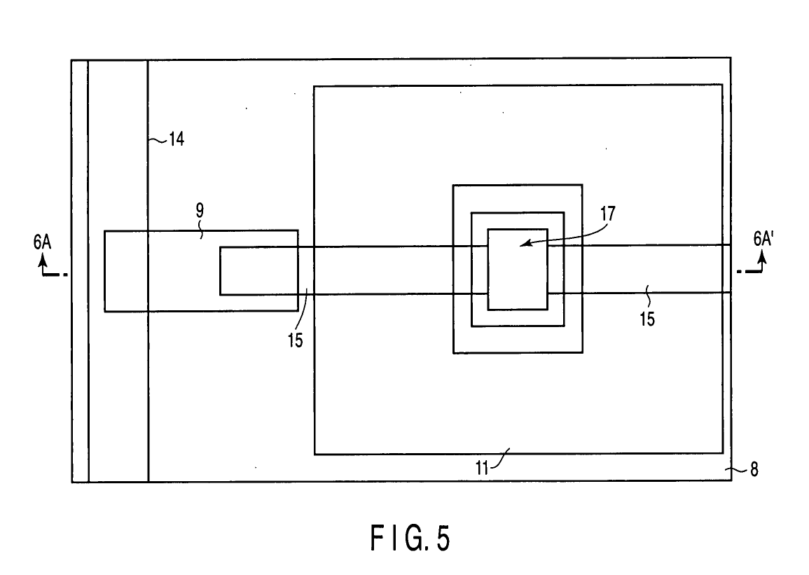

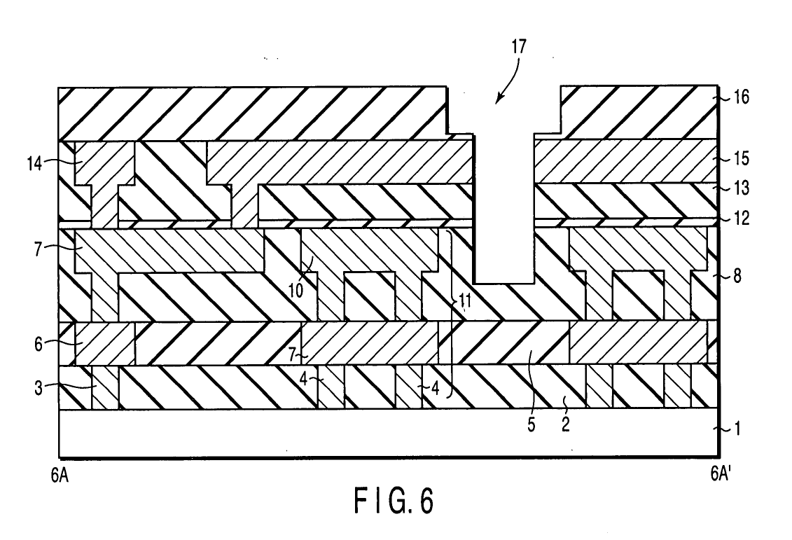

FIG. 5 is a top plan view showing a semiconductor device including a fuse interconnect according to the third embodiment of the present invention. FIG. 6 is a cross-sectional view taken along the line 6A-6A′ of FIG. 5. FIG. 5 and FIG. 6 show a state that the fuse interconnect is cut.

The present embodiment differs from the second embodiment in that the outer and inner interconnects 7 and the outer and inner damascene interconnects 10 are respectively integrated in the moisture absorption preventing hollow member 11. Thereby, it is possible to more effectively prevent moisture 84 from intruding into the circuit of the device. Besides, the same effect as the first embodiment is obtained, and modifications are possible like the first embodiment.

In FIG. 5 and FIG. 6, for simplification, there is shown an example that the interconnects 7 and 10 of the double-structural moisture absorption preventing hollow member 11 are integrated, however, a structure that each interconnect of three or more layers of moisture absorption preventing hollow member 11 can be integrated respectively can be used.

### FOURTH EMBODIMENT

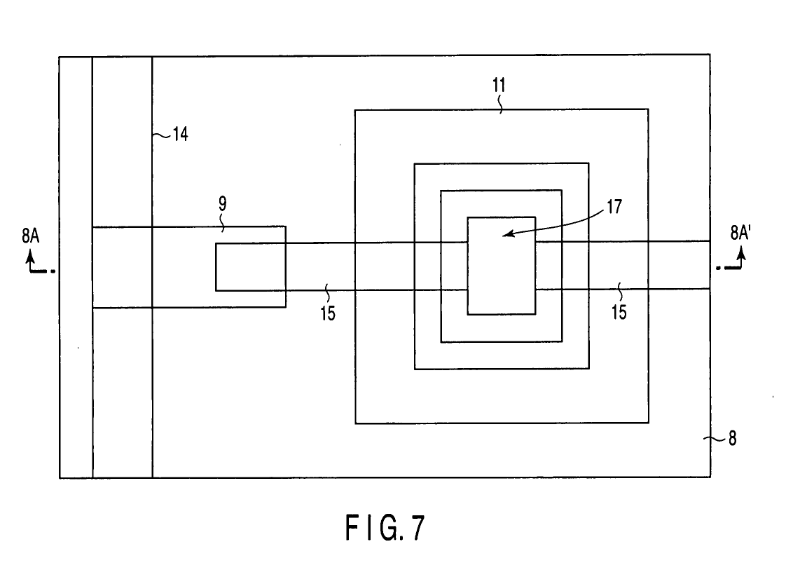

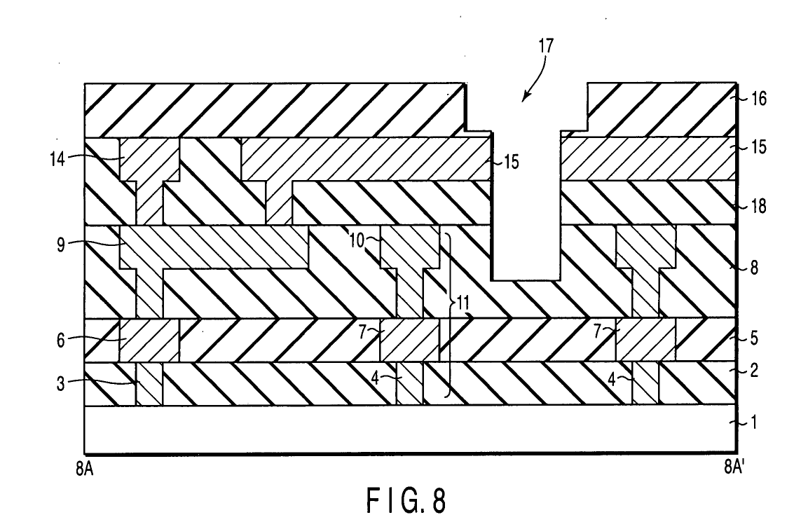

FIG. 7 is a top plan view showing a semiconductor device including a fuse interconnect according to the fourth embodiment of the present invention. FIG. 8 is a cross-sectional view taken along the line 8A-8A′ of FIG. 7. FIG. 7 and FIG. 8 show a state that the fuse interconnect is cut.

The present embodiment differs from the first embodiment in that Al or W is used as the interconnect material, the moisture absorption preventing film 12 is omitted, and the damascene interconnect 14 and the fuse interconnect 15 are formed in an moisture absorption preventing film (fourth interlayer insulating film) 18.

The moisture absorption preventing film 18 is a silicon oxide film containing nitrogen, for example. The silicon oxide film is formed by plasma CVD process. In this case, SiH₄ gas is used as the source gas.

In a case that the interconnect material is Al, the moisture absorption preventing film 12 need not have the anti-diffusion function for the interconnect material (plug material). Thereby, in the case that the interconnect material is Al, the role for the moisture absorption preventing film 12 can be given to the fourth interlayer insulating film. Therefore, it is possible to omit the moisture absorption preventing film 12, and simplification can be achieved in structure and process. Besides, the same effect as the first embodiment is obtained, and modifications are possible like the first embodiment.

### FIFTH EMBODIMENT

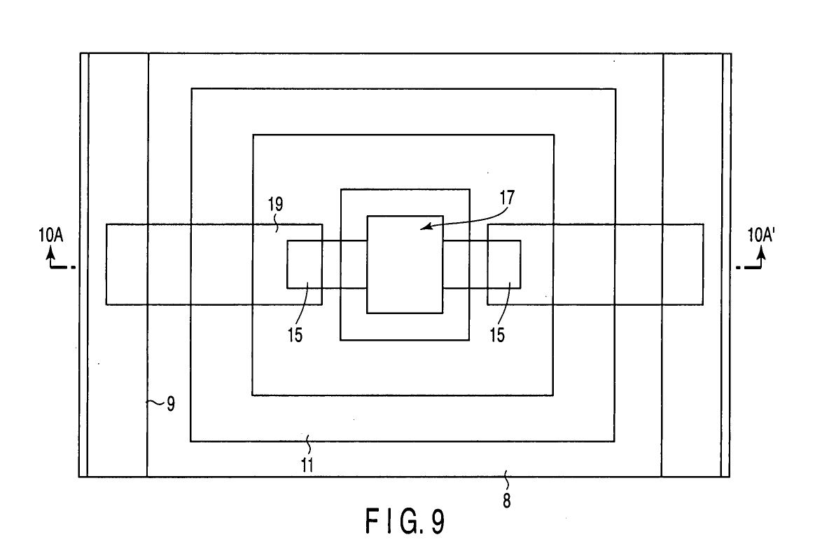

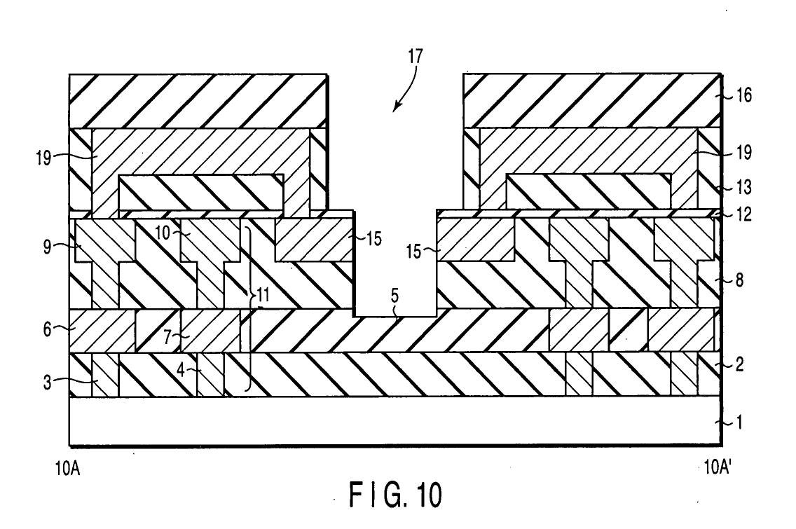

FIG. 9 is a top plan view showing a semiconductor device including a fuse interconnect according to the fifth embodiment of the present invention. FIG. 10 is a cross-sectional view taken along the line 10A-10A′ of FIG. 9. FIG. 9 and FIG. 10 show a state that the fuse interconnect is cut.

The present embodiment differs from the first embodiment in that a layer formed with the moisture absorption preventing hollow member 11 (layer formed with the damascene interconnect 9) is formed with the fuse interconnect 15. The fuse interconnect 15 and the damascene interconnect 9 are connected by an interconnect 19 (connection interconnect). In the first embodiment, the fuse interconnect 15 is formed in the layer higher than the moisture absorption preventing hollow member 11.

In the present embodiment, the same effect as the first embodiment is obtained, and modifications are possible like the first embodiment.

The present invention is not limited to the embodiments described above. For instance, in the embodiments, the moisture absorption preventing hollow member 11 is formed of the same conductive material as the interconnect material, however, the moisture absorption preventing hollow member 11 can be formed of an insulating material having the moisture absorption preventing effect. For example, silicon nitride, silicon carbide, carbon doped silicon nitride are give as the insulating material having the moisture absorption preventing effect. The unit of the fuse interconnect which is provided with the moisture absorption preventing hollow member can be one fuse interconnect or plural fuse interconnects

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor device comprising:
a semiconductor substrate;
a multilayer interconnect provided on the semiconductor substrate, the multilayer interconnect comprising a plurality of layers of insulating films and interconnects;
at least one fuse interconnect provided in a layer higher than the multilayer interconnect; and
a moisture absorption preventing hollow member including a hollow structure, the moisture absorption preventing hollow member selectively surrounding the at least one fuse interconnect and reaching a surface of the semiconductor substrate through the multilayer interconnect, the moisture absorption preventing hollow member comprising a material having a lower hygroscopicity than the plurality of layers of insulating films.

2. A semiconductor device comprising:
a semiconductor substrate;
a multilayer interconnect provided on the semiconductor substrate, the multilayer interconnect comprising a plurality of layers of insulating films and interconnects;
at least one fuse interconnect provided in the multilayer interconnect; and
an moisture absorption preventing hollow member including a hollow structure, the moisture absorption preventing hollow member selectively surrounding the at least one fuse interconnect and reaching the surface of the semiconductor substrate through the multilayer interconnect, moisture absorption preventing hollow member comprising a material having a lower hygroscopicity than the plurality of layers of insulating films.

3. The semiconductor device according to claim 1, wherein the plurality of layers of insulating films include an insulating film having a dielectric constant of 3.8 or less.

4. The semiconductor device according to claim 2, wherein the plurality of layers of insulating films include an insulating film having a dielectric constant of 3.8 or less.

5. The semiconductor device according to claim 3, wherein the insulating film having the dielectric constant of 3.8 or less is an fluorine doped silicon oxide film (SiOF) formed by plasma CVD process, carbon doped silicon oxide film (SiOC) formed by plasma CVD process, organic coating insulating film formed from resin having siloxane bond as a main structure, organic coating insulating film formed from resin having C—C bond as a main structure or organic coating insulating film formed from resin having C═C bond as a main structure.

6. The semiconductor device according to claim 4, wherein the insulating film having the dielectric constant of 3.8 or less is an insulating film comprising at least one of fluorine doped silicon oxide film (SiOF), carbon doped silicon oxide film (SiOC), organic coating insulating film formed from resin having siloxane bond as a main structure, organic coating insulating film formed from resin having C—C bond as a main structure or organic coating insulating film formed from resin having C═C bond as a main structure.

7. The semiconductor device according to claim 1, wherein the moisture absorption preventing hollow member is a multiple-structural moisture absorption preventing hollow member which includes a first moisture absorption preventing hollow member, and a second moisture absorption preventing hollow member surrounding the first moisture absorption preventing hollow member.

8. The semiconductor device according to claim 2, wherein the moisture absorption preventing hollow member is a multiple-structural moisture absorption preventing hollow member which includes a first moisture absorption preventing hollow member, and a second moisture absorption preventing hollow member surrounding the first moisture absorption preventing hollow member.

9. The semiconductor device according to claim 3, wherein the moisture absorption preventing hollow member is a multiple-structural moisture absorption preventing hollow member which includes a first moisture absorption preventing hollow member, and a second moisture absorption preventing hollow member surrounding the first moisture absorption preventing hollow member.

10. The semiconductor device according to claim 4, wherein the moisture absorption preventing hollow member is a multiple-structural moisture absorption preventing hollow member which includes a first moisture absorption preventing hollow member, and a second moisture absorption preventing hollow member surrounding the first moisture absorption preventing hollow member.

11. The semiconductor device according to claim 1, wherein the moisture absorption preventing hollow member comprises a conductive material.

12. The semiconductor device according to claim 1, wherein the moisture absorption preventing hollow member comprises the same material as the plurality of layers of interconnects.

13. The semiconductor device according to claim 1, wherein the moisture absorption preventing hollow member placed in the same layer as the plurality of interconnects comprises the same material as an interconnect placed in the same layer as the plurality of interconnects.

14. The semiconductor device according to claim 1, wherein the multilayer interconnect further comprises a plurality of plugs, and the moisture absorption preventing hollow member placed in the same layer as the plurality of plugs comprises the same material as a plug placed in the same layer as the plurality of plugs.

15. The semiconductor device according to claim 1, wherein the plurality of interconnects includes Cu al or W as a material.

16. The semiconductor device according to claim 1, wherein the fuse interconnect is cut, and an opening is provided in a surface of the plurality layers of insulating films which lies beneath a portion where the fuse interconnect is cut.

17. The semiconductor device according to claim 16, further comprising:
a passivation film provided in a layer higher than the multilayer interconnect; and
a fuse window provided in the passivation film on a portion where the fuse interconnect is cut, and connecting to the opening.

18. The semiconductor device according to claim 1, wherein the fuse interconnect is provided in an insulating film, and at least one of silicon oxide film, silicon nitride film, carbon doped silicon nitride film and silicon carbide film is provided between the insulating film and the multilayer interconnect.

19. The semiconductor device according to claim 1, wherein the at least one interconnect comprises a plurality of interconnects, and the moisture absorption preventing hollow member is provided with respect to each of the plural fuse interconnects.

20. The semiconductor device according to claim 1, wherein the at least one interconnect comprises a plurality of interconnects, the moisture absorption preventing hollow member is provided to surround the plurality of interconnects.
